(19) United States
(12) Patent Application Publication
(10) Pub. No.: US 2007/0223711 A1
(43) Pub. Date: Sep. 27, 2007

(54) System and method for visualizing sound source energy distribution

(76) Inventors: Mingsian R. Bai, Hsinchu City (TW); Jia-Hong Lin, Lujhu Township (TW); Yu-Wei Ning, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/439,286

(22) Filed: May 24, 2006

(30) Foreign Application Priority Data
Mar. 1, 2006 (TW) 95106887

(51) Int. Cl. H04R 29/00; H03G 3/00; G06F 17/00

(52) U.S. Cl. 381/56; 381/61; 700/94

(57) ABSTRACT

The present invention discloses a system for visualizing sound source energy distribution and a method thereof, wherein a propagation matrix and a window matrix are obtained firstly; next, an inverse operation of the propagation matrix is performed; next, a multiplication operation of the result of the inverse operation and the window matrix is performed; next, the result of the multiplication operation is transformed from the time domain to the frequency domain; thus, a sound source energy distribution reconstructor is established; then, an array of microphones is used to receive the sound source signals; next, a multi-channel capture device transforms the received sound source signals into digital sound source signals; lastly, a convolution operation is performed on the digital sound source signals and the sound source energy distribution reconstructor to obtain a visualized sound source energy distribution. Therefore, the present invention can provide the energy distributions of nearfield/farfield stable-state/unstable-state sound sources.

### BACKGROUND OF THE INVENTION

1. Field of the Invention

The present invention relates to a technology for visualizing sound source energy distribution, particularly to a system utilizing an inverse operation technology to visualize sound source energy distribution and a method thereof.

2. Description of the Related Art

With the advance of science and technology, people demand higher and higher living-environment quality. However, the living environment is full of the noise induced by structural vibration, which may cause physiological and psychological problems.

The effect of noise control correlates closely with the correctness of positioning and identifying noise sources. Therefore, it is essential for noise control to accurately trace and correctly identify the sources of noise. Only after the position, source strength distribution, particle velocity distribution, and intensity distribution of a structural-vibration-induced noise have been obtained should the noise be correctly estimated, optimally controlled and effectively reduced. When the noise-control technology is applied to the diagnosis of power machines, it can assist the engineers to correctly identify the source of a malfunction and estimate the influence thereof.

As to the conventional technologies of sound source identification, there is an article “Determination of Directivity of a Planar Noise Source by Means of Near Field Acoustical Holography, 2: Numerical Simulation” by M. A. Rowell and D. J. Oldham, J. Sound and Vibration, 1995, which utilizes a nearfield acoustical holography to determine noise sources. However, the nearfield acoustical holography can only identify the distribution of the acoustic field on a nearfield plane. Further, the calculation thereof needs to perform coordinate transformation several times, which is apt to cause a spatial aliasing. Besides, such a technology is also disadvantaged by needing a multitude of microphones. There is also a US patent of Publication No. 20050225497 proposing a sound source-identification method implemented by a beam forming array technology. However, the beam forming array technology can only identify a farfield acoustic field and is not so effective in identifying an unstable-state sound source. Besides, such a technology is also disadvantaged by that it cannot perform calculation instantly, that it cannot synchronically identify the acoustic fields of different coordinate systems, and that it needs to modify the configuration of the microphone array to avoid a spatial aliasing.

Accordingly, the present invention proposes a system for visualizing sound source energy distribution and a method thereof to overcome the abovementioned problems.

### SUMMARY OF THE INVENTION

The primary objective of the present invention is to provide a system for visualizing sound source energy distribution and a method thereof, which utilizes an inverse-operation technology to establish a sound source energy distribution reconstructor in order to obtain the energy distributions of nearfield/farfield stable-state/unstable-state sound sources or the sound source energy distribution of an arbitrary frequency band.

Another objective of the present invention is to provide a system for visualizing sound source energy distribution and a method thereof, which can utilizes fewer in-array microphones to obtain the energy distributions of planar or non-planar sound sources and is advantaged by wide identifiable frequency band, no reference signal, less spatial aliasing, allowance of an irregular microphone array, the capability of instant calculation, and the capability of synchronically obtaining the energy distributions of the sound sources of different coordinate systems.

In the present invention, a propagation matrix and a window matrix are obtained via assigning values to the coordinates of arrayed microphones and assigning values to the coordinates of the retreated focus points on the retreated focus point surface; next, an inverse operation of the propagation matrix is performed; next, a multiplication operation of the window matrix and the result of the inverse operation is performed; then, the result of the multiplication operation is displaced from the frequency domain to the time domain by an Inverse Fast Fourier Transform operation. Thereby, a sound source energy distribution reconstructor is established. Next, arrayed microphones are used to receive the signals of sound sources, and a multi-channel capture device is used to transform the sound source signals into digital sound source signals. Next, a convolution operation of the digital sound source signals and the sound source energy distribution reconstructor is performed to obtain the sound source energy distribution on the retreated focus point surface, and the sound source energy distribution is presented on an output device. The propagation matrix is obtained with the formula:

$$\frac{{ⅇ}^{- j {kr}_{MN}}}{{r}_{MN}} ,$$

wherein r_{MN} is the distance between the coordinate of the Nth retreated focus point and the coordinate of the Mth in-array microphone, and k is the wave number

$$( k = \frac{ω}{c} = \frac{2 π f}{c} , c = 343 m \text{/} s ) .$$

The window matrix is obtained via: defining a boundary of the retreated focus point surface, assigning 1 to the coordinates of the retreated focus points inside the boundary, and assigning 0 to the coordinates of the retreated focus points outside the boundary. The sound source energy distribution reconstructor utilizes ERA (Eigensystem Realization Algorithm) to transform the convolution operation to a state space to undertake a synchronic MIMO operation. Further, the retreated focus point surface method is used to obtain the sound source energy distribution on a reconstructed surface and accomplish a higher accuracy of the sound source energy distribution.

To enable the objectives, technical contents, characteristics, and accomplishments of the present invention to be more easily understood, the embodiments of the present invention are to be described in detail in cooperation with the attached drawings below.

### BRIEF DESCRIPTION OF THE DRAWINGS

FIG. 1(a) is a diagram schematically showing the principle of establishing a sound source energy distribution reconstructor according to the present invention.

FIG. 1(b) is a flowchart showing the process of establishing a sound source energy distribution reconstructor and utilizing the sound source energy distribution reconstructor to obtain a sound source energy distribution according to the present invention.

FIG. 2 is a diagram schematically showing the establishment of a window matrix according to the present invention.

FIG. 3 is a diagram schematically the architecture of the system according to the present invention.

FIG. 4(a) is a diagram showing the beam pattern output by the sound source energy distribution reconstructor without a window matrix and with a window matrix according to the present invention.

FIG. 4(b) is a diagram showing the beam pattern output by the sound source energy distribution reconstructor with a window matrix according to the present invention.

FIG. 5 is a diagram showing the distribution of singular values according to the present invention.

FIG. 6 is a diagram schematically showing that the array of microphones is arranged into a one-dimensional linear microphone array according to the present invention.

FIG. 7 is a diagram showing the sound source strength distribution obtained via the measurement of sound source signals by a one-dimensional linear microphone array according to the present invention.

FIG. 8 is a diagram schematically showing that the array of microphones is arranged into a two-dimensional linear microphone array according to the present invention.

FIG. 9 is a diagram showing the digital sound source signal distribution obtained by a two-dimensional linear microphone array according to the present invention.

FIG. 10 is a diagram showing the sound source strength distribution obtained via the measurement of sound source signals by a two-dimensional linear microphone array according to the present invention.

FIG. 11 is a diagram schematically showing that a retreated focus point surface method is used to build a reconstructed surface according to the present invention.

FIG. 12 is a diagram showing the sound source pressure distribution on a reconstructed surface obtained with the retreated focus point surface method according to the present invention.

FIG. 13 is a diagram showing the sound source particle velocity distribution on a reconstructed surface according to the present invention.

FIG. 14 is a diagram showing the sound source intensity distribution on a reconstructed surface according to the present invention.

FIG. 15 is a diagram showing the sinc function.

FIG. 16 is a diagram showing the gauss function.

FIG. 17 is a diagram schematically showing that a synthetic aperture method is used to obtain a sound source energy distribution with the angle contained by the sound source energy distribution and the array of microphones less than θ degrees according to the present invention.

### DETAILED DESCRIPTION OF THE INVENTION

The present invention proposes a system for visualizing sound source energy distribution and a method thereof, which utilizes an inverse-operation technology to establish a sound source energy distribution reconstructor and obtain the energy distributions of sound sources.

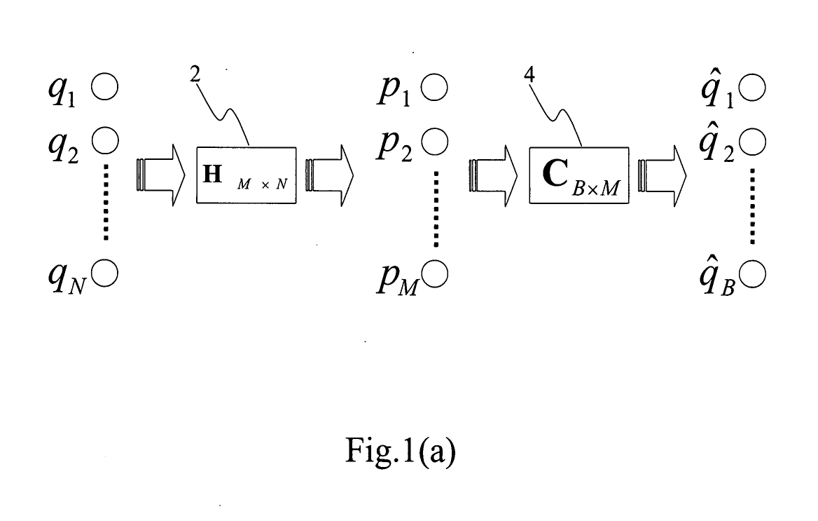

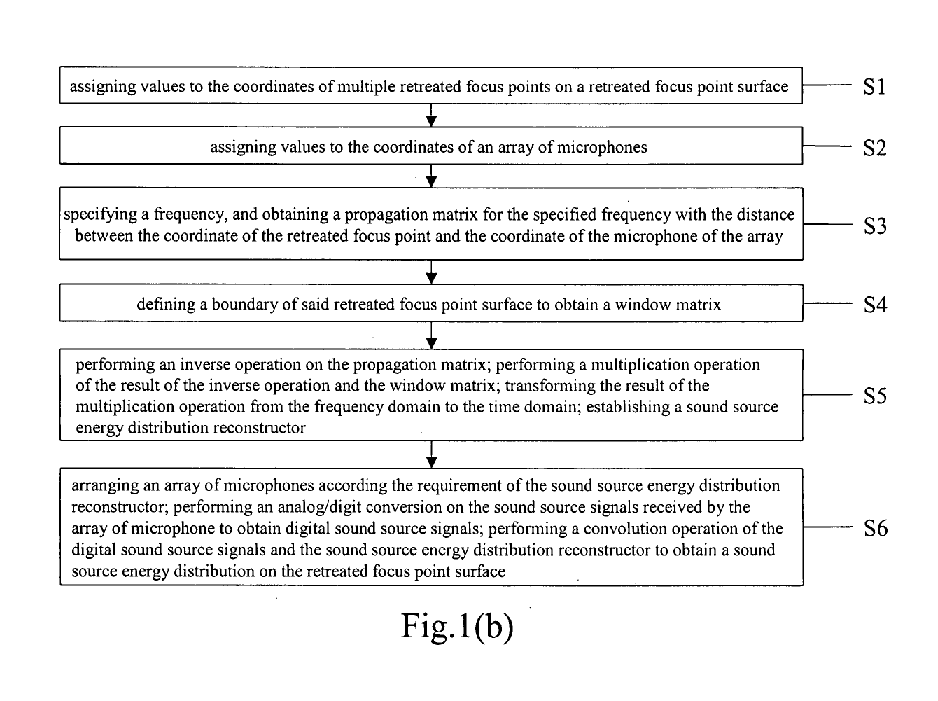

Firstly, the principle and steps of establishing a sound source energy distribution reconstructor will be described below. Refer to FIG. 1(a) and FIG. 1(b). In Step S1, values are assigned to the coordinates q₁, q₂ . . . q_{N} of the retreated focus points on the retreated focus point surface, and it is supposed that multiple point sources are located at the retreated focus points. In Step S2, values are assigned to the coordinates p₁, p₂ . . . p_{M} of the arrayed microphones. In Step 3, Formula (1):

$$\frac{{ⅇ}^{- j {kr}_{MN}}}{{r}_{MN}} \qquad ( 1 )$$

is used to work out a propagation matrix (2), wherein r_{MN} is the distance between the coordinate of the Nth retreated focus point and the coordinate of Mth in-array microphone, and k is the wave number

$$( k = \frac{ω}{c} = \frac{2 π f}{c} , c = 343 m \text{/} s ) .$$

In Step S3, based on the k value obtained by specifying the frequency and the distance between the coordinate of a retreated focus point and the coordinate of an in-array microphone, a propagation matrix (2) for a given frequency can be obtained with Formula (1); the propagation matrix (2) is expressed by:

$${H}_{M \times N} = [ \begin{matrix}H ( {r}_{11} ) & H ( {r}_{12} ) & ⋯ & H ( {r}_{1 N} ) \\ H ( {r}_{12} ) & H ( {r}_{21} ) & ⋯ & H ( {r}_{2 N} ) \\ ⋮ & ⋮ & ⋰ & ⋮ \\ H ( {r}_{M 1} ) & H ( {r}_{M1} ) & ⋯ & H ( {r}_{MN} )\end{matrix} ] \qquad ( 2 )$$

wherein H(r_{MN}) is obtained via Formula (1) and denotes the pressure that the Mth in-array microphone receives from the point source at the Nth retreated focus point. The relation of those three matrices is expressed by Formula (3):

$$[ \begin{matrix}{p}_{1} \\ {p}_{2} \\ ⋮ \\ {p}_{M}\end{matrix} ] = [ \begin{matrix}H ( {r}_{11} ) & H ( {r}_{12} ) & ⋯ & H ( {r}_{1 N} ) \\ H ( {r}_{21} ) & H ( {r}_{22} ) & ⋯ & H ( {r}_{2 N} ) \\ ⋮ & ⋮ & ⋰ & ⋮ \\ H ( {r}_{M 1} ) & H ( {r}_{M 2} ) & ⋯ & H ( {r}_{MN} )\end{matrix} ] [ \begin{matrix}{q}_{1} \\ {q}_{2} \\ ⋮ \\ {q}_{N}\end{matrix} ] \qquad ( 3 )$$

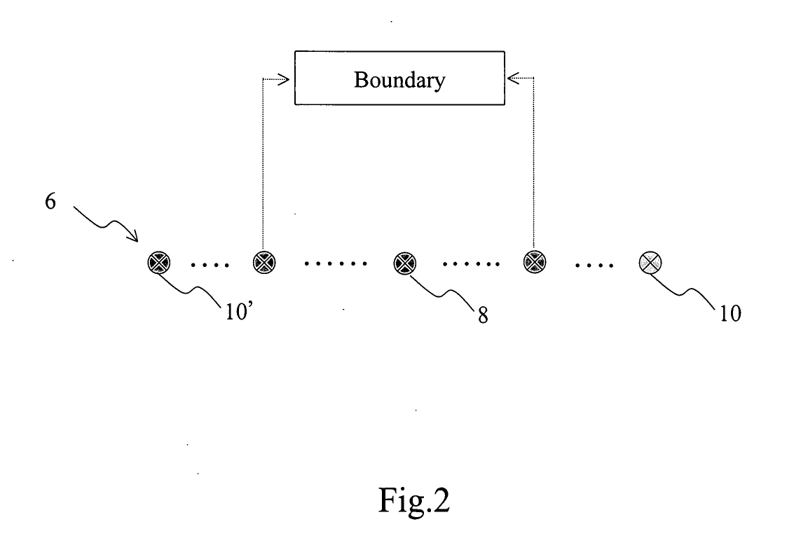

Refer to FIG. 2. In Step S4, a boundary of the retreated focus point surface 6 is defined, and 1 is assigned to the retreated focus points 8 inside the boundary, wherein the total number of them amounts to B, and 0 is assigned to the retreated focus points 10 and 10′ outside the boundary; thus, a window matrix (4) is obtained and expressed by:

$$W = [ \begin{matrix}0 & 0 & 0 & 0 & 0 & 0 & 0 & 0 & 0 \\ 0 & ⋰ & 0 & 0 & 0 & 0 & 0 & 0 & 0 \\ 0 & 0 & 0 & 0 & 0 & 0 & 0 & 0 & 0 \\ 0 & 0 & 0 & {1}_{1} & 0 & 0 & 0 & 0 & 0 \\ 0 & 0 & 0 & 0 & ⋰ & 0 & 0 & 0 & 0 \\ 0 & 0 & 0 & 0 & 0 & {1}_{B} & 0 & 0 & 0 \\ 0 & 0 & 0 & 0 & 0 & 0 & 0 & 0 & 0 \\ 0 & 0 & 0 & 0 & 0 & 0 & 0 & ⋰ & 0 \\ 0 & 0 & 0 & 0 & 0 & 0 & 0 & 0 & 0\end{matrix} ] . \qquad ( 4 )$$

In Step S5, an inverse operation of the propagation matrix (2) is performed; next, a multiplication operation of the window matrix (4) and the result of the inverse operation is performed to obtain an inverse matrix C_{B×M} 4; then, the inverse matrix C_{B×M} 4 is transformed from the frequency domain to the time domain by an Inverse Fast Fourier Transform operation. Thereby, a sound source energy distribution reconstructor is established.

In Step S6, according to the requirement of the sound source energy distribution reconstructor, an array of microphones is arranged. Multiple sound source signals are received by the arrayed microphones and transformed into multiple digital sound source signals by a multi-channel capture device. A convolution operation of the digital sound source signals and the sound source energy distribution reconstructor is performed to obtain the sound source energy distribution \hat{q}₁, \hat{q}₂ . . . \hat{q}_{B} on the retreated focus point surface 6, wherein the total number of them amounts to B.

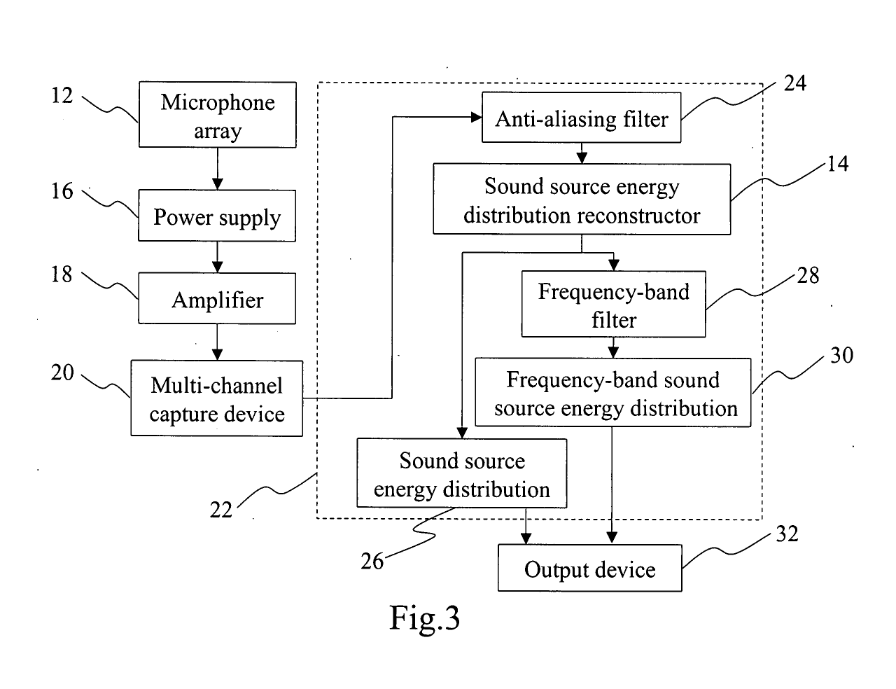

Refer to FIG. 3 a diagram schematically showing the architecture of the present invention. After the microphone array 12 has been arranged according to the sound source energy distribution reconstructor 14, the arrayed microphones receive multiple sound source signals. The sound source energy distribution reconstructor 14 works out the ratio of the maximum singular value and the minimum singular value of the propagation matrix to determine the distance from a sound source signal to the in-array microphone receiving the sound source signal. When the ratio of the maximum singular value and the minimum singular value is equal to or smaller than 1000, the acoustic field is determined to be a nearfield one. When the ratio of the maximum singular value and the minimum singular value is greater than 1000, the acoustic field is determined to be a farfield one. Next, the sound source signals pass through a MIMO power supply 16 and an amplifier 18 and then enter into a multi-channel capture device 20. The multi-channel capture device 20 transforms the analog sound source signals into digital sound source signals. The digital sound source signals are transmitted to a computer system 22, and the succeeding operations of the digital sound source signals will be performed in the computer system 22. In the computer system 22, an anti-aliasing filter 24 performs a filtering operation on the digital sound source signals. Then, the filtered digital sound source signals are transmitted to a sound source energy distribution reconstructor 14, and a convolution operation of the digital sound source signals and the reconstructor 14 is performed to obtain a sound source energy distribution 26 on the retreated focus point surface, wherein the sound source energy distribution 26 may be a source strength distribution, a particle velocity distribution, or an intensity distribution. Further, a frequency-band filter 28 may be used to filter the sound source energy distribution 26 obtained by the reconstructor 14 to obtain the frequency-band sound source energy distribution 30 of the desired frequency band. Finally, The computer system 22 transmits the sound source energy distribution 26 or the frequency-band sound source energy distribution 30 to an output device 32, such as a computer monitor. Thus, via the output device 32, the user can view the sound source energy distribution or the frequency-band sound source energy distribution to identify the position of the sound source and analyze the distribution of the acoustic field.

To speak briefly, the present invention firstly establishes a sound source energy distribution reconstructor, and next, an array of microphones is arranged according to the requirement of the reconstructor; next, an analog/digital conversion is performed to transform the received analog sound source signals into digital sound source signals; then, a convolution operation of the digital sound source signals and the sound source energy distribution reconstructor is performed to obtain the energy distribution of the sound source.

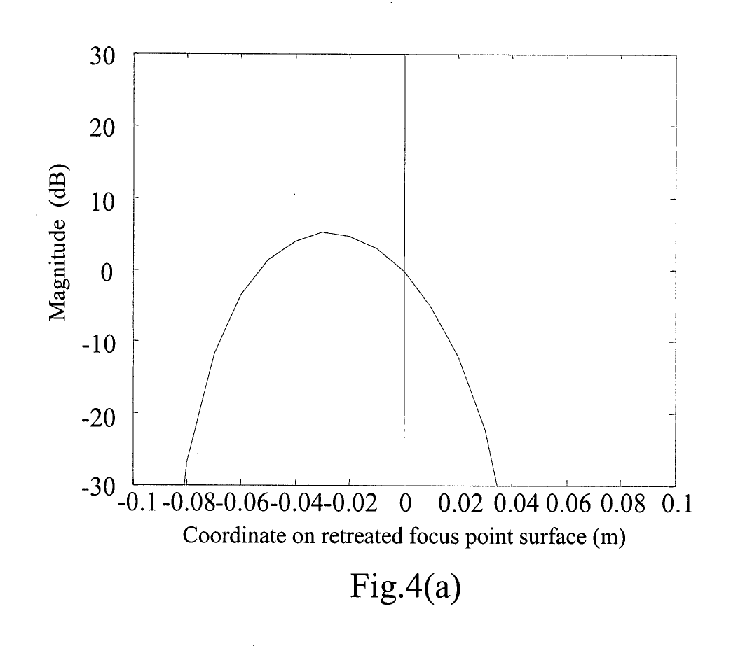

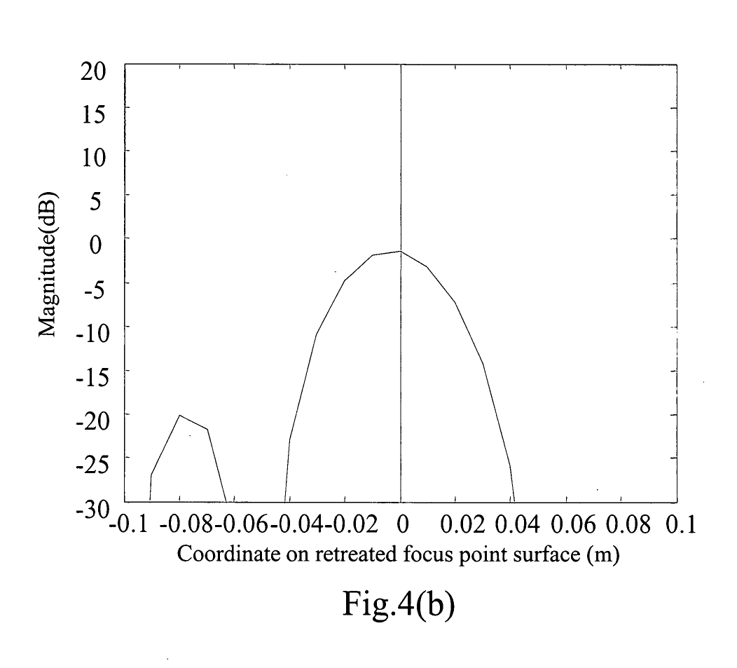

In the present invention, the window matrix is used to increase the identification accuracy in the boundary of the sound source so that the error of the estimated sound source energy distribution can be minimized. Refer to FIG. 4(a) and FIG. 4(b) diagrams showing the beam patterns on the left boundary (0 m) output by the sound source energy distribution reconstructors without a window matrix and with a window matrix respectively. It can be found from those two diagrams: the beam output by the reconstructor with a window matrix can more accurately point to the boundary than that output by the reconstructor without a window matrix. Therefore, the window matrix used in the present invention can increase the accuracy in identifying the sound source on the boundary of the acoustic field.

When the coordinates of the arrayed microphones are less than those of the retreated focus points, the present invention utilizes an under-determined architecture to enable that the sound source energy distribution reconstructor can use a right inverse operation to obtain the result of the inverse operation of the propagation matrix H_{M×N}. Thereby, a sound source energy distribution reconstructor, which is suitable for the case that the coordinates of the arrayed microphones are less those of the retreated focus points, can be established.

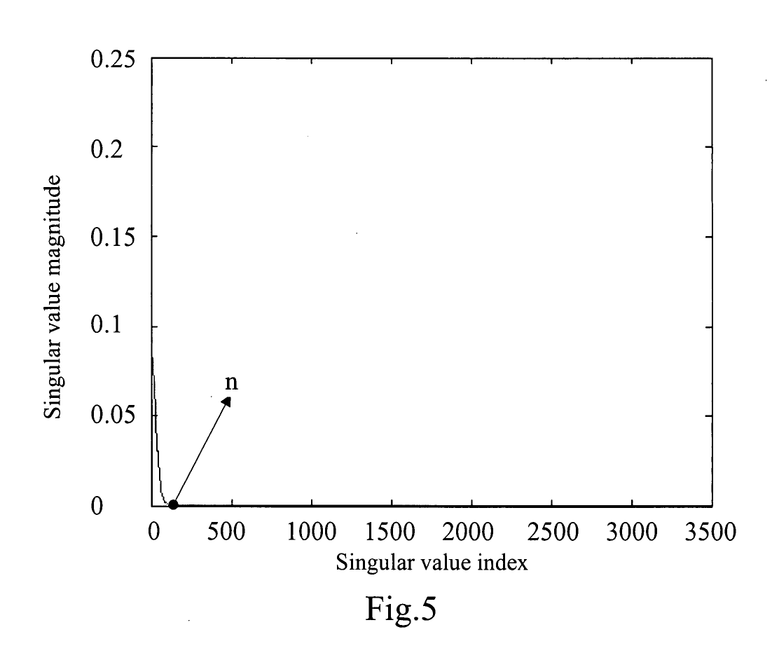

To reduce the calculation of the convolution operation of the digital sound source signals and the sound source energy distribution reconstructor, and to promote the efficiency of the sound source energy distribution reconstructor, the present invention utilize ERA (Eigensystem Realization Algorithm) to enable the convolution operation of the digital sound source signals and the sound source energy distribution reconstructor to be calculated in a state space. Firstly, the impulse responses of the sound source energy distribution reconstructor are arranged into a Hankel matrix, and an SVD (Singular Value Decomposition) operation is performed on the Hankel matrix. Refer to FIG. 5 a diagram showing the singular-value distribution after the SVD operation of the Hankel matrix has been performed. As shown in the diagram, the singular value index after an n point become very small, which means that the data after the n point is redundant and can be omitted. Therefore, the operation will only use the singular value index before the n point, and a matrix degradation can be thus achieved. The formulation of the Eigensystem Realization Algorithm is performed on the deflated Hankel matrix to obtain four primary matrix parameters of the state-space operation. Then, a state-space operation is performed on the digital sound source signals to obtain the energy distribution of the sound source. Thus, the Eigensystem Realization Algorithm used in the present invention can reduce the quantity of the addition and multiplication operations of the sound source energy distribution reconstructor and can achieve a synchronic MIMO effect.

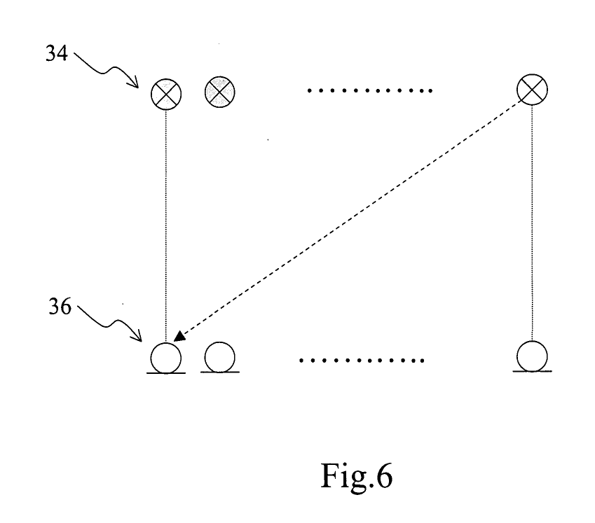

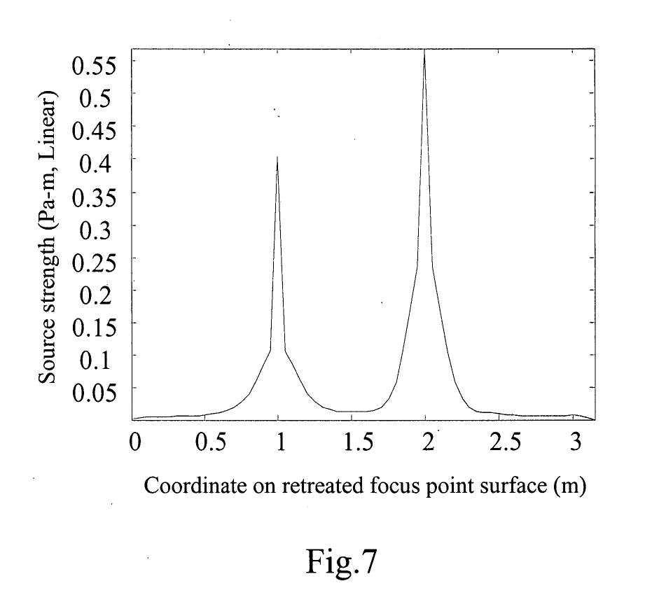

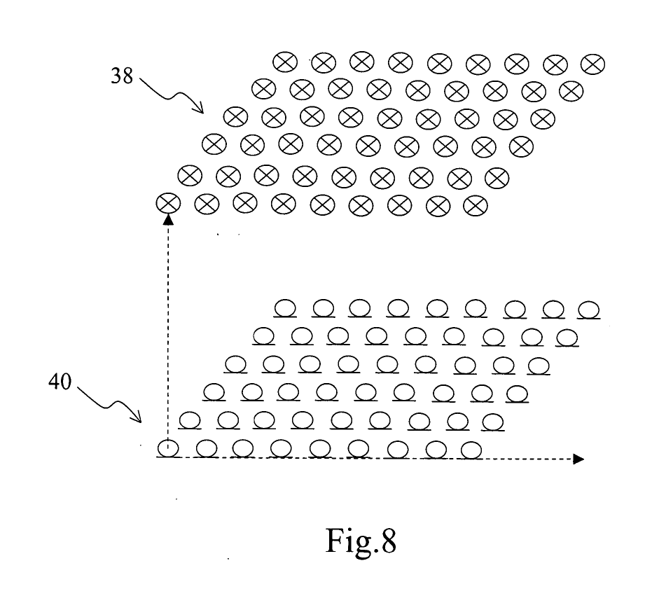

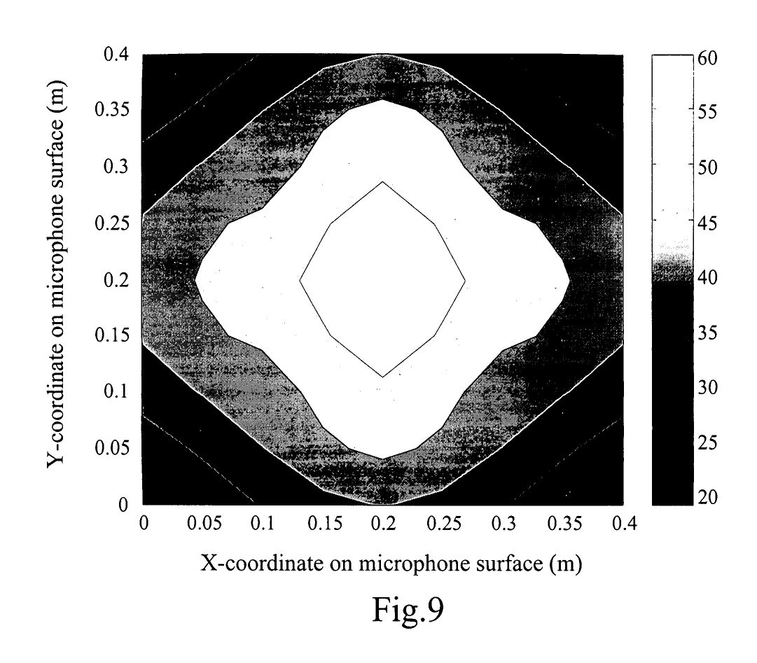

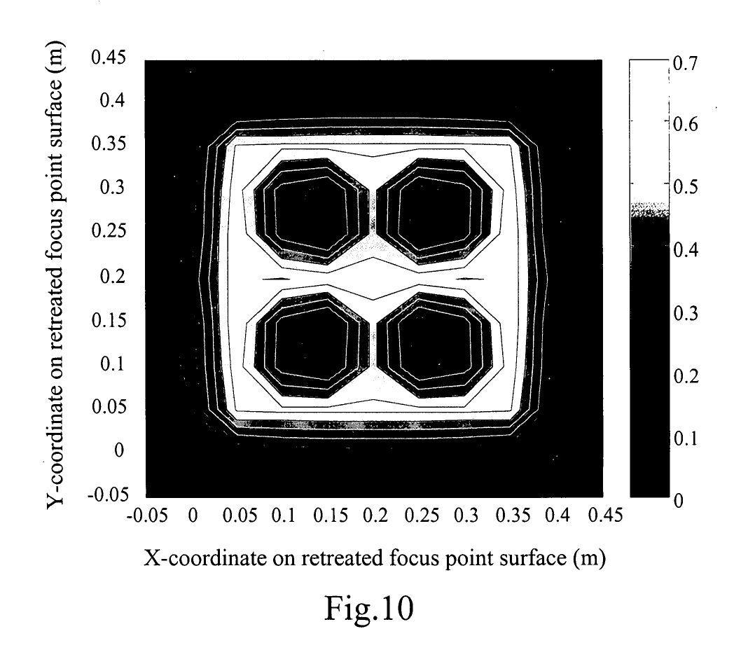

Refer to FIG. 6. The array of microphones of the present invention may be arranged into a one-dimensional linear microphone array 36 to receive the sound source signals 34. The received sound source signals are transformed into digital sound source signals by a multi-channel capture device. A convolution operation of the digital sound source signals and the sound source energy distribution reconstructor is performed to obtain a sound source energy distribution on the retreated focus point surface. Refer to FIG. 7 a diagram showing the source strength distribution of sound sources. As shown in the diagram, there are sound sources existing at the positions 1 m and 2 m to the retreated focus point surface. Refer to FIG. 8. The array of microphones of the present invention may be arranged into a two-dimensional linear microphone array 40 to receive the sound source signals 38. The received sound source signals are transformed into digital sound source signals by a multi-channel capture device. A convolution operation of the digital sound source signals and the sound source energy distribution reconstructor is performed to obtain a higher-resolution sound source energy distribution on the retreated focus point surface. When the sound sources on the retreated focus point surface are arranged like a checkerboard, the sound source signals 38 received by the two-dimensional linear microphone array 40 are transformed into digital sound source signals by the multi-channel capture device to obtain the distribution of the digital sound source signals shown in FIG. 9. The unit of the distribution of the digital sound source signals is Pa-m, linear. Then, a convolution operation of the digital sound source signals and the sound source energy distribution reconstructor is performed to obtain a higher-resolution sound source strength distribution on the retreated focus point surface shown in FIG. 10, wherein the interval between two neighboring retreated focus points is 0.05 m. The unit of the sound source strength distribution is Pa-m, linear. Besides, the arrayed microphones of the present invention may also be irregularly arranged.

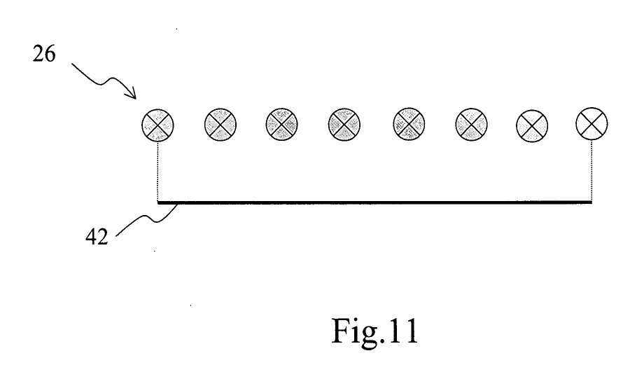

Refer to FIG. 11. To further promote the resolution of the acoustic field, after the sound source energy distribution reconstructor has obtained the sound source energy distribution 26 on the retreated focus point surface, the retreated focus point surface method is used to establish a reconstructed surface 42 to obtain a higher-resolution sound source energy distribution on the reconstructed surface 42. The retreated focus point surface method utilizes Formula (5) to calculate the sound source energy distribution on the reconstructed surface 42, and Formula (5) is expressed by:

$$\frac{A}{r} {ⅇ}^{- j kr} \qquad ( 5 )$$

wherein A is the sound source energy distribution 26 on the retreated focus point surface, r is the distance from the retreated focus point on the retreated focus point surface to the focus point on the reconstructed surface 42, and k is the wave number

$$( k = \frac{ω}{c} = \frac{2 π f}{c} , c = 343 m \text{/} s ) .$$

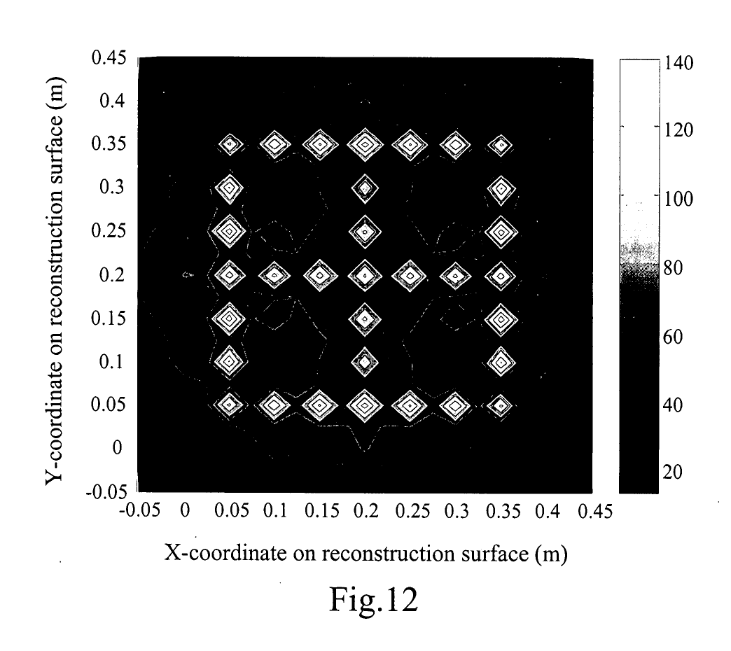

Refer to FIG. 12 a diagram showing a sound source pressure distribution on the reconstructed surface, wherein the interval between two neighboring focuses is 0.0025 m. The unit of the sound source pressure distribution is Pa, linear. Via comparing FIG. 12 with FIG. 10, it is known that the retreated focus point surface method not only can be used to promote the resolution of a sound source energy distribution, but also can be used to observe the resolution of sound source identification and the spatial resolution of an acoustic field distribution reconstructor.

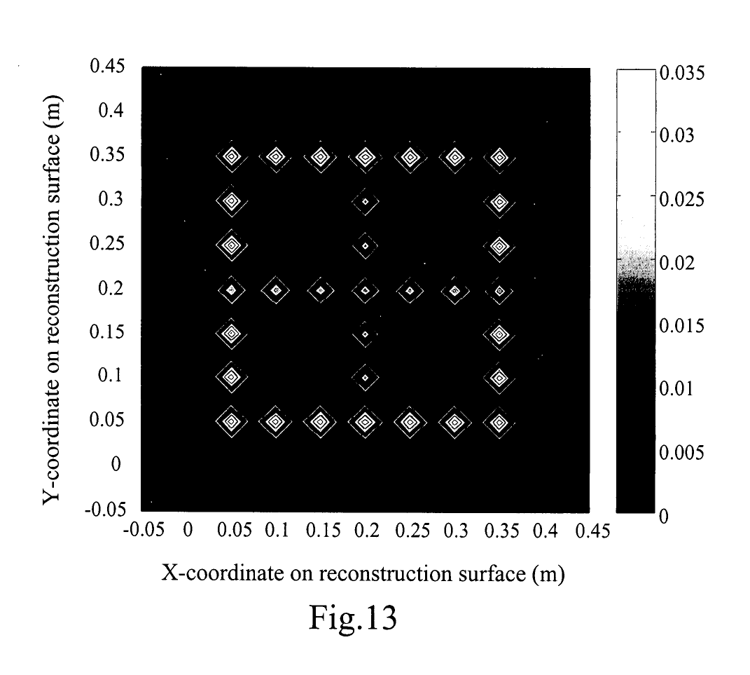

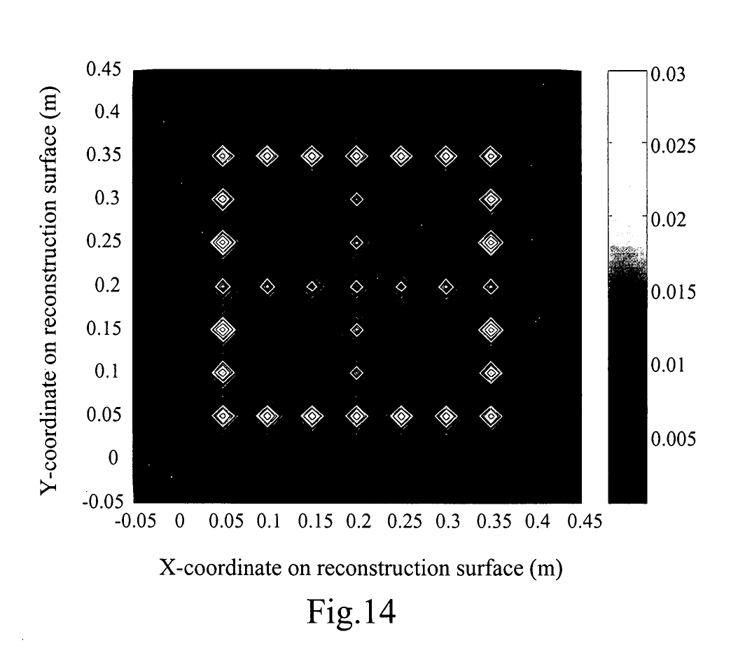

The acoustic field distribution not only can be observed in a sound source pressure distribution but also can be observed in a sound source particle velocity distribution or a sound source intensity distribution. Refer to FIG. 13 and FIG. 14 diagrams respectively showing a sound source particle velocity distribution and a sound source intensity distribution. The unit of the sound source particle velocity distribution is m/s, and the unit of the sound source intensity distribution is W/m². From those two diagrams, it is known that the acoustic field distribution can be more clearly observed from a sound source particle velocity distribution or a sound source intensity distribution.

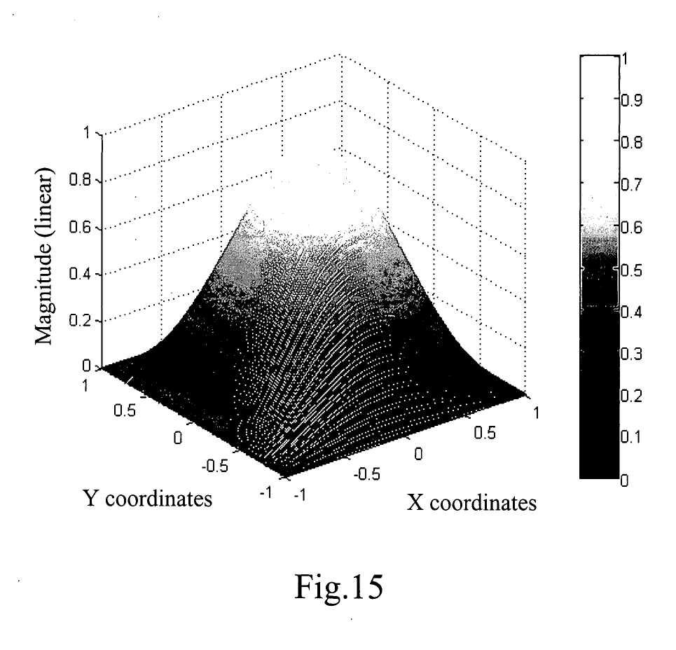

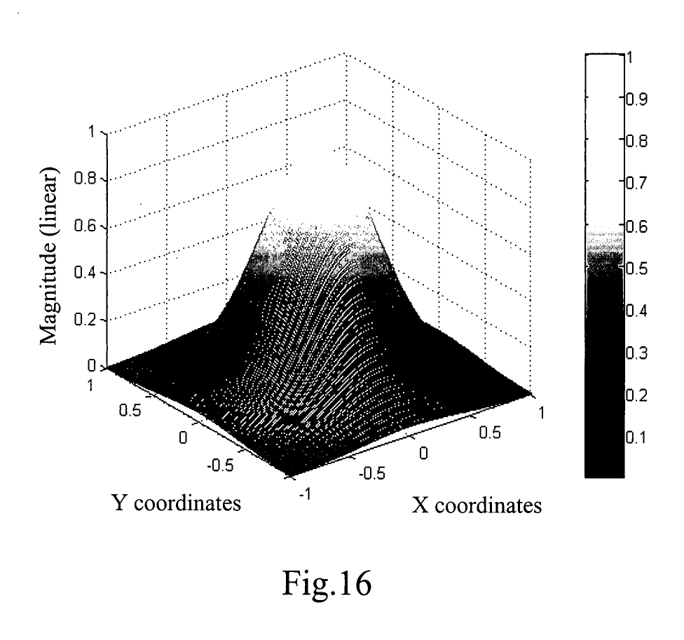

The present invention can further perform an image interpolation operation on a sound source energy distribution so that the sound source energy distribution can be output to an output device with a higher resolution. The image interpolation operation may be implemented with the sinc function or the gauss function; FIG. 15 and FIG. 16 are diagrams respectively showing the sinc function and the gauss function.

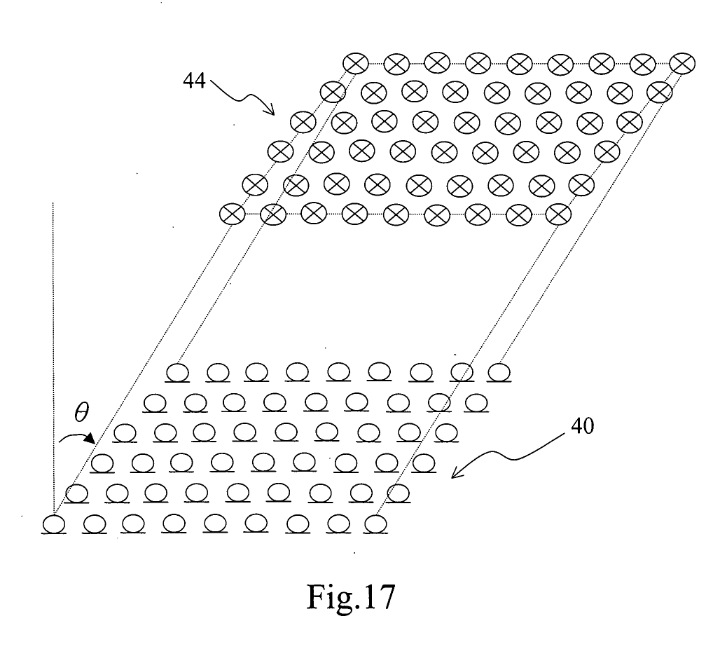

In order to synchronically obtain the sound source energy distributions of different coordinate systems without moving the arrayed microphones and the test objects, the present invention further utilizes a synthetic aperture method to enable that the maximum rotation angle of a measurement aperture can reach 30 degrees. A convolution operation of the digital sound source signals originally received by the arrayed microphones and the sound source energy distribution reconstructor is performed to obtain a sound source energy distribution on the retreated focus point surface inside the rotated aperture. Refer to FIG. 17 a diagram schematically showing that the present invention utilizes the synthetic aperture method to obtain a retreated focus point surface 44 with the angle contained by the retreated focus point surface 44 and the two-dimensional linear microphone array 40 less than 30 degrees. Thereby, the present invention has the advantage that the identifiable acoustic field can be synchronically enlarged.

In summary, the present invention obtains different propagation matrices via assigning different values to the frequency and has the advantage of wide identifiable frequency band. Further, the present invention needs fewer transformations so that the present invention can be advantaged in less spatial aliasing. Besides, the present invention is also advantaged in that no reference signal is needed.

The system and method of the present invention, which utilizes the abovementioned inverse operation technology and performs the operation within the time domain, can effectively identify the positions of sound sources and obtain the distribution of the acoustic field. The present invention can solve the problems of the conventional technologies that the nearfield and farfield sound source energy distributions cannot be synchronically obtained, and the operation cannot be instantly performed. The system for visualizing sound source energy distribution and the method thereof proposed by the present invention not only can obtain the energy distributions of nearfield/farfield stable-state/unstable-state sound sources or the sound source energy distribution of an arbitrary frequency band, but also can utilizes fewer microphones to obtain the energy distributions of planar or non-planar sound sources. Furthermore, the present invention is advantaged by wide identifiable frequency bands, no reference signal, less spatial aliasing, allowance of an irregular microphone array, the capability of instant calculation, and the capability of synchronically obtaining the energy distributions of the sound sources of different coordinate systems.

Those embodiments described above are to clarify the present invention to enable the persons skilled in the art to understand, make and use the present invention; however, it is not intended to limit the scope of the present invention, and any equivalent modification and variation according to the spirit of the present invention is to be also included within the scope of the claims stated below.

What is claimed is:

1. A system for visualizing sound source energy distribution, comprising:
an array of microphones, used to receive multiple sound source signals;
a multi-channel capture device, transforming said sound source signals into multiple digital sound source signals; and
a sound source energy distribution reconstructor,
wherein a propagation matrix and a window matrix is obtained via assigning values to the coordinates of said array of microphones and assigning values to the coordinates of multiple retreated focus points on a retreated focus point surface; an inverse operation is performed on said propagation matrix; a multiplication operation of the result of said inverse operation and said window matrix is performed; the result of said multiplication operation is transformed from the frequency domain to the time domain to establish said sound source energy distribution reconstructor; after said sound source energy distribution reconstructor has received said digital sound source signals, a convolution operation of said digital sound source signals and said sound source energy distribution reconstructor is performed to obtain a sound source energy distribution on said retreated focus point surface.

2. The system for visualizing sound source energy distribution according to claim 1, wherein said array of microphones is a one-dimensional linear microphone array or a two-dimensional linear microphone array.

3. The system for visualizing sound source energy distribution according to claim 1, wherein said array of microphones is arranged according to the requirement of said sound source energy distribution reconstructor to receive said sound source signals.

4. The system for visualizing sound source energy distribution according to claim 1, wherein said propagation matrix is obtained with a formula:
$$\frac{{ⅇ}^{- j {kr}_{MN}}}{{r}_{MN}} ,$$
wherein r_{MN} is the distance between the coordinate of the Nth said retreated focus point and the coordinate of the Mth microphone in said array, and k is the wave number
$$( k = \frac{ω}{c} = \frac{2 π f}{c} , c = 343 m \text{/} s ) .$$

5. The system for visualizing sound source energy distribution according to claim 1, wherein said window matrix is obtained via: defining a boundary of said retreated focus point surface, assigning 1 to the coordinates of said retreated focus points inside said boundary, and assigning 0 to the coordinates of said retreated focus points outside said boundary.

6. The system for visualizing sound source energy distribution according to claim 1, wherein an Inverse Fast Fourier Transform operation is used to transform the result of said multiplication operation from the frequency domain to the time domain.

7. The system for visualizing sound source energy distribution according to claim 1, wherein said sound source energy distribution may be a source strength distribution, a particle velocity distribution, or an intensity distribution.

8. The system for visualizing sound source energy distribution according to claim 1, wherein an under-determined architecture is used to enable that the coordinates of the microphones in said array can be less than the coordinates of said retreated focus points, and a right inverse operation can be used to obtain the result of said inverse operation of said propagation matrix.

9. The system for visualizing sound source energy distribution according to claim 1, wherein said sound source energy distribution reconstructor utilizes ERA (Eigensystem Realization Algorithm) to transform said convolution operation of said digital sound source signals and said sound source energy distribution reconstructor to a state space to undertake a synchronic MIMO operation.

10. The system for visualizing sound source energy distribution according to claim 1, wherein said sound source energy distribution reconstructor utilizes a synthetic aperture method to obtain a sound source energy distribution via said digital sound source signals with the angle contained by said sound source energy distribution and said array of microphones less than 30 degrees.

11. The system for visualizing sound source energy distribution according to claim 1, wherein said sound source energy distribution reconstructor utilizes a retreated focus point surface method to obtain a sound source energy distribution on a reconstructed surface from said sound source energy distribution.

12. The system for visualizing sound source energy distribution according to claim 11, wherein the formula of said retreated focus point surface method is:
$$\frac{A}{ r} {ⅇ}^{- j kr}$$
wherein A is said sound source energy distribution on said retreated focus point surface, and r is the distance between said retreated focus point on said retreated focus point surface to a focus point on said reconstructed surface, and k is the wave number
$$( k = \frac{ω}{ c} = \frac{2 π f}{ c} , c = 343 m \text{/} s ) .$$

13. The system for visualizing sound source energy distribution according to claim 1, wherein said sound source energy distribution reconstructor utilizes an image interpolation method to perform an image interpolation operation on said sound source energy distribution to obtain a higher-resolution sound source energy distribution.

14. The system for visualizing sound source energy distribution according to claim 13, wherein said image interpolation operation may be implemented with the sinc function or the gauss function.

15. The system for visualizing sound source energy distribution according to claim 1, further comprising: a frequency-band filter, which performs a filtering operation on said sound source energy distribution to obtain a sound source energy distribution of a desired frequency band.

16. The system for visualizing sound source energy distribution according to claim 1, further comprising: an output device, which is used to output or present the data of said sound source energy distribution.

17. A method for visualizing sound source energy distribution, comprising the following steps:
(a) assigning values to the coordinates of an array of microphones, and assigning values to the coordinates of multiple retreated focus points on a retreated focus point surface;
(b) specifying a frequency, and obtaining a propagation matrix with the distance between the coordinate of said retreated focus point and the coordinate of the microphone of said array, and obtaining a window matrix via: defining a boundary of said retreated focus point surface, assigning 1 to the coordinates of said retreated focus points inside said boundary, and assigning 0 to the coordinates of said retreated focus points outside said boundary;
(c) performing an inverse operation on said propagation matrix;
performing a multiplication operation of the result of said inverse operation and said window matrix; transforming the result of said multiplication operation from the frequency domain to the time domain; establishing a sound source energy distribution reconstructor;
(d) receiving multiple sound source signals via an array of microphones, and transforming said sound source signals into multiple digital sound source signals via a multi-channel capture device; and
(e) performing an convolution operation of said digital sound source signals and said sound source energy distribution reconstructor to obtain a sound source energy distribution on said retreated focus point surface.

18. The method for visualizing sound source energy distribution according to claim 17, wherein said array of microphones is a one-dimensional linear microphone array or a two-dimensional linear microphone array.

19. The method for visualizing sound source energy distribution according to claim 17, wherein said propagation matrix is obtained with a formula:
$$\frac{{ⅇ}^{- j {kr}_{MN}}}{{r}_{MN}} ,$$
wherein r_{MN} is the distance between the coordinate of the Nth said retreated focus point and the coordinate of the Mth microphone in said array, and k is the wave number
$$( k = \frac{ω}{c} = \frac{2 π f}{c} , c = 343 m \text{/} s ) .$$

20. The method for visualizing sound source energy distribution according to claim 17, wherein in step (c), when the coordinates of said retreated focus points is more than the coordinates of the microphones in said array, an under-determined architecture is used to perform a right inverse operation of said propagation matrix to obtain the result of said inverse operation of said propagation matrix.

21. The method for visualizing sound source energy distribution according to claim 17, wherein in step (d), said array of microphones is arranged according to the requirement of said sound source energy distribution reconstructor to receive said sound source signals.

22. The method for visualizing sound source energy distribution according to claim 17, wherein in step (e), ERA (Eigensystem Realization Algorithm) is used to transform said convolution operation to a state space to undertake a synchronic MIMO operation.

23. The method for visualizing sound source energy distribution according to claim 17, further comprising: said sound source energy distribution reconstructor utilizing a synthetic aperture method to obtain a sound source energy distribution via said digital sound source signals with the angle contained by said sound source energy distribution and said array of microphones less than 30 degrees.

24. The method for visualizing sound source energy distribution according to claim 17, wherein in step (e), a retreated focus point surface method is used to establish a reconstructed surface form said sound source energy distribution and obtain a sound source energy distribution on said reconstructed surface.

25. The method for visualizing sound source energy distribution according to claim 24, wherein the formula of said retreated focus point surface method:
$$\frac{A}{r} {ⅇ}^{- j kr}$$
wherein A is said sound source energy distribution on said retreated focus point surface, r is the distance between said retreated focus point on said retreated focus point surface to the focus point on said reconstructed surface, and k is the wave number
$$( k = \frac{ω}{c} = \frac{2 π f}{c} , c = 343 m \text{/} s ) .$$

26. The method for visualizing sound source energy distribution according to claim 17, wherein in step (e), an image interpolation method is used to perform an image interpolation operation on said sound source energy distribution to obtain a higher-resolution sound source energy distribution.

27. The method for visualizing sound source energy distribution according to claim 26, wherein said image interpolation operation may be implemented with the sinc function or the gauss function.

28. The method for visualizing sound source energy distribution according to claim 17, wherein in step (e), a frequency-band filter is used to perform a filtering operation on said sound source energy distribution to obtain a sound source energy distribution of a desired frequency band.

29. The method for visualizing sound source energy distribution according to claim 17, wherein in step (e), an output device is used to output or present the data of said sound source energy distribution.
